(19) United States
(12) Patent Application Publication
(10) Pub. No.: US 2023/0387877 A1
(43) Pub. Date: Nov. 30, 2023

(54) Integrated Acoustic Devices

(71) Applicant: The Government of the United States of America, as represented by the Secretary of the Navy, Arlington, VA (US)

(72) Inventors: Vikrant J. GOKHALE, Alexandria, VA (US); Brian P. DOWNEY, Cheverly, MD (US); Shawn C. MACK, Alexandria, VA (US); D. Scott KATZER, Alexandria, VA (US); David J. MEYER, Annandale, VA (US); Pallavi DHAGAT, Corvallis, OR (US); Albrecht JANDER, Corvallis, OR (US)

(73) Assignee: The Government of the United States of America, as represented by the Secretary of the Navy, Arlington, VA (US)

(21) Appl. No.: 18/315,560

(22) Filed: May 11, 2023

Related U.S. Application Data
(60) Provisional application No. 63/344,084, filed on May 20, 2022.

(51) Int. Cl. H03H 3/02; H03H 3/007

(52) U.S. Cl. CPC H03H 3/02; H03H 3/0077; H03H 2003/027

(57) ABSTRACT

Method for forming an integrated acoustic device. A thin film piezoelectric acoustic transducer is epitaxially formed on a host substrate and is then transferred to a functional target substrate wherein physical phenomena from the piezoelectric transducer and the arbitrary functional substrate interact to form a hybrid acoustic microsystem comprising the piezoelectric transducer and the arbitrary functional substrate.

### CROSS-REFERENCE

This application is a Nonprovisional of and claims the benefit of priority under 35 U.S.C. § 119 based on U.S. Provisional Patent Application No. 63/344,084 filed on May 20, 2022. The Provisional Application and all references cited herein are hereby incorporated by reference into the present disclosure in their entirety.

### FEDERALLY-SPONSORED RESEARCH AND DEVELOPMENT

The United States Government has ownership rights in this invention. Licensing inquiries may be directed to Office of Technology Transfer, US Naval Research Laboratory, Code 1004, Washington, DC 20375, USA; +1.202.767.7230; techtran@nrl.navy.mil, referencing Navy Case #211081.

### TECHNICAL FIELD

The present disclosure relates to the field of acoustic transducers and methods for making the same.

### BACKGROUND

Conventionally, thin film piezoelectric materials deposited or grown on a supporting substrate have been used to fabricate surface acoustic wave (SAW) and bulk acoustic wave (BAW) devices. For some device configurations such as high overtone bulk acoustic wave resonators (HBARs) and phononic cavities, the entire substrate is part of the acoustic device. For other configurations such as thin-film-on-substrate (TPOS) resonators, solidly mounted resonators (SMRs), and film bulk acoustic resonators (FBARs), the layer or few layers directly underneath the grown/deposited piezoelectric thin film are part of the acoustic device. For other configurations (SAW or solidly mounted Lamb wave devices), properties of the substrate near the interface with the piezoelectric film are critical to performance. Some high power RF acoustic devices need a substrate with a high thermal conductivity to act as a heat sink and a piezoelectric-substrate interface with a low thermal boundary resistance. Many acoustic device configurations require a metallic electrode layer directly under the piezoelectric films.

The rich diversity in microscale acoustic devices is reflected in their widespread use as sensors, high-frequency acoustic transducers, or as resonators, oscillators and filters in analog radio frequency (RF) signal processing systems. Group III-Group V (III-V) alloys, which includes Group III-Nitride (III-N) materials, are some of the most popular piezoelectric thin films used for making acoustic devices.

The inventors of the present invention have previously designed, developed, and characterized epi-HBARs grown on SiC substrates using molecular beam epitaxy (MBE). See U.S. Patent Application Publication No. 2021/0091746 to V. J. Gokhale, et al., entitled “Multifunctional Integrated Acoustic Devices and Systems Using Epitaxial Materials” (2021); V. J. Gokhale, et al., “Epitaxial bulk acoustic wave resonators as highly coherent multi-phonon sources for quantum acoustodynamics,” Nature Communications, vol. 11, p. 2314, 2020; and V. J. Gokhale, et al., “Temperature evolution of frequency and anharmonic phonon loss for multi-mode epitaxial HBARs,” Applied Physics Letters, vol. 117, p. 124003, 2020.

A large amount of scientific and commercial progress has been made in material discovery, wafer-scale film growth/deposition, optimization, and system integration, in order to improve the quality and the functionality of these thin film piezoelectric acoustic devices. Successful growth/deposition techniques rely on physical or chemical vapor deposition or epitaxy of the piezoelectric thin film on to the surface of an appropriate substrate wafer.

The crystal structure, quality, orientation, and surface morphology of the growth/deposition surface are critical factors in determining the crystal structure, quality, orientation, and surface morphology of the piezoelectric thin film grown or deposited on the substrate. All of these factors are important material parameters that set the acoustic performance parameters of any devices created from these piezoelectric films.

As an illustrative example, consider the popular III-N piezoelectric scandium aluminum nitride (SLAIN). High quality c-axis textured SLAIN films can be sputter deposited at low temperatures (˜300° C.) on to Pt or Mo layers on top of Si wafers. See S. Mertin, et al., “Piezoelectric and structural properties of c-axis textured aluminium scandium nitride thin films up to high scandium content,” Surface and Coatings Technology, vol. 343, pp. 2-6, 2018; and S. Mertin, et al., “High-Volume Production and Non-Destructive Piezo-Property Mapping of 33% SC Doped Aluminium Nitride Thin Films,” in 2018 IEEE International Ultrasonics Symposium (IUS), 2018, pp. 1-4.

The fixed crystallinity, orientation, stress, and surface roughness of the Si substrate wafer and the Pt or Mo layers, as well as tight control of the process parameters during sputter deposition are needed to achieve polycrystalline ScAlN thin films that can be used practically for making acoustic devices.

Alternately, single-crystal c-axis ScAlN can be grown using molecular beam epitaxy (MBE) on c-axis 4H—SiC. See M. T. Hardy, et al., “Control of phase purity in high scandium fraction heteroepitaxial ScAlN grown by molecular beam epitaxy,” Applied Physics Express, vol. 13, p. 065509, 2020. The MBE process results in lower loss ScAlN thin films with better crystal structure, but the process control requirements are even more stringent and the films are often grown at higher temperatures (˜700° C.).

The use of some alternative substrates such as 6H—SiC, sapphire, and Si have been demonstrated, but each alternative requires a large amount of process development and might involve a compromise in the quality of the grown/deposited piezoelectric thin film.

Other desirable materials (e.g. magnets or multiferroics) cannot be used as substrates at all, or result in a low quality piezoelectric film structure because of process incompatibility or a structural mismatch with the piezoelectric film to be grown/deposited.

Advances in materials science and thin film technology have slightly increased the number of materials and acoustic device combinations available for practical applications. The availability of both sputter deposited or epitaxially grown high Sc-fraction ScAlN is a recent development. The growth of ScAlN on crystalline metallic transition metal nitride (TMN) is one option for ScAlN on a metallic electrode. The use of TMN interlayers enables not just high quality piezoelectric III-N films, but also enables the growth of electronic grade piezoelectric semiconductors such as GaN and AlGaN.

However, a large amount of research and development has gone into each of these capabilities, and it is either impractical or impossible to replicate this on other substrates or heterostructures.

### SUMMARY

This summary is intended to introduce, in simplified form, a selection of concepts that are further described in the Detailed Description. This summary is not intended to identify key or essential features of the claimed subject matter, nor is it intended to be used as an aid in determining the scope of the claimed subject matter. Instead, it is merely presented as a brief overview of the subject matter described and claimed herein.

The present invention provides a method to create integrated acoustic microstructures and microsystems that combine an epitaxially grown thin film piezoelectric device with the unique physical properties and capabilities of an arbitrary substrate which might not be appropriate for use in the optimized epitaxial growth process.

In accordance with the present invention, epitaxial techniques are used to grow and fabricate high quality thin film microacoustic devices on a host growth substrate. Subsequently, a transfer-printing technique is used to lift the individual devices off the host substrate, and place them onto a target functional substrate that itself forms an integral part of the acoustic device, where the functional substrate imparts not just mechanical support to the transferred thin film device, but also adds its unique physical properties and capabilities to the overall integrated acoustic device or microsystem formed by the acoustic device and the functional substrate.

This fabrication approach in accordance with the present invention decouples the growth, fabrication, and material optimization of a piezoelectric acoustic transducer from the choice of functional target substrates that are themselves unsuitable for epitaxy, but which provide access to a range of physical phenomena (electrical, optical, thermal, magnetic) that can be coupled with acoustic waves/phonons.

### BRIEF DESCRIPTION OF THE DRAWINGS

FIGS. 1A and 1B are block schematics illustrating aspects of a transfer printing method for making an integrated magnetoelastic high-overtone bulk acoustic resonator (ME-HBAR) in accordance with the present invention.

FIG. 2 is a block schematic illustrating an exemplary ME-HBAR device fabricated using the transfer printing process in accordance with the present invention.

FIGS. 3A-3D are microscopic images of devices released from their host substrate before (FIGS. 3A and 3B) and after (FIG. 3C) being transfer printed onto a target substrate.

FIGS. 4A-4D are plots illustrating the RF reflection spectra and performance of an epitaxial HBAR and an ME-HBAR after transfer printing onto a YIG substrate in accordance with the present invention.

FIGS. 5A-5C illustrate aspects of the performance of ME-HBAR devices fabricated using a transfer printing process in accordance with the present invention.

FIGS. 6A-6C further illustrate aspects of the performance of ME-HBAR devices made by the transfer printing process in accordance with the present invention.

FIGS. 7A-7D are block schematics illustrating exemplary alternative ME-HBAR devices that can be fabricated using the transfer printing process in accordance with the present invention.

### DETAILED DESCRIPTION

The aspects and features of the present invention summarized above can be embodied in various forms. The following description shows, by way of illustration, combinations and configurations in which the aspects and features can be put into practice. It is understood that the described aspects, features, and/or embodiments are merely examples, and that one skilled in the art may utilize other aspects, features, and/or embodiments or make structural and functional modifications without departing from the scope of the present disclosure.

The present invention provides a method to create integrated acoustic microstructures and microsystems that combine an epitaxially grown thin film piezoelectric device with the unique physical properties and capabilities of an arbitrary substrate which might not be appropriate for use in the optimized epitaxial growth process.

As described in more detail below, the fabrication approach in accordance with the present invention enables the creation of a variety of acoustic heterostructures with a wide choice of substrate and heterostructure combinations by decoupling the growth process from the choice of eventual substrate or substrate heterostructure, and combining the most optimally grown piezoelectric transducer and device with an arbitrary target substrate that may not be compatible with the original growth process. The transfer is mediated via the transfer printing process originally developed for the heterogeneous integration of electronic chiplets.

In accordance with the present invention, epitaxial techniques are used to grow and fabricate high quality thin film microacoustic devices on a host growth substrate. Subsequently, a transfer-printing technique is used to lift the individual devices off the host substrate, and place them onto a target functional substrate that itself forms an integral part of the acoustic device, where the functional substrate imparts not just mechanical support to the transferred thin film device, but also adds its unique physical properties and capabilities to the overall integrated acoustic device or microsystem formed by the acoustic device and the functional substrate.

This fabrication approach in accordance with the present invention decouples the growth, fabrication, and material optimization of a piezoelectric acoustic transducer from the choice of functional target substrates that are themselves unsuitable for epitaxy, but which provide access to a range of physical phenomena (electrical, optical, thermal, magnetic) that can be coupled with acoustic waves/phonons.

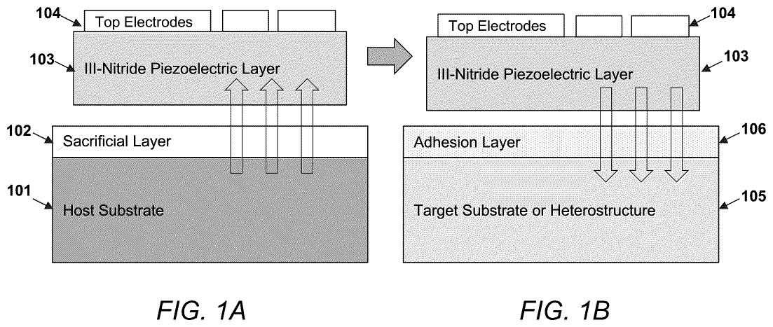

The block schematics in FIGS. 1A and 1B illustrate aspects of an exemplary embodiment of the method for creating an acoustic heterostructure in accordance with the present invention.

In this exemplary embodiment, the method of the present invention is employed with an epitaxially grown piezoelectric transducer, which can be in the form of a piezoelectric thin film or piezoelectric heterostructure such as that illustrated in FIGS. 1A and 1B. As illustrated in FIG. 1A, such a structure comprises an epitaxial III-nitride piezoelectric transducer layer and/or a perovskite oxide (PO) piezoelectric transducer layer 103 grown on a transition metal nitride (TMN) sacrificial layer 102, which in turn is epitaxially grown on a host substrate 101, where the host substrate is selected to provide the best growth platform for the device. One or more patterned top metal electrodes 104 are deposited on an upper surface of the III-Nitride piezoelectric layer 103 to provide electrical contact to the acoustic device. One skilled in the art will readily recognize that any one or more of the layers described above may also require additional nucleation layers or template layers in order to achieve the best performance, and such template layers are not separately described here. For example, a high quality electronic-grade GaN layer often requires a very thin AlN layer as a buffer.

Piezoelectric transducer layer 103 may be etched down to form a finite structure and shape based on the design of the desired acoustic device. Similarly, top metal electrode(s) 104 can be in the form of simple squares or circles, in the form of any other planar design, or in the form of an interdigitated transducer (IDT), as appropriate for the design of the desired acoustic device. In some embodiments, the top metal electrode(s) 104 can comprise a single electrical port or multiple electrical ports, as per the design of the desired acoustic device.

Once the structure in FIG. 1A is formed, sacrificial layer 102 is etched away, with such etching being done using any appropriate method or any appropriate etchant. For example, the etchant can be a liquid or gas phase etchant, and in some embodiments could require slightly elevated process temperatures to control the reaction rate.

Once sacrificial layer 102 is etched away, as illustrated in FIG. 1B, the released piezoelectric transducer layer 103 is removed from the host substrate 101 and placed onto a target substrate or target heterostructure 105, which will eventually form part of the acoustic device. Target substrate 105 can take any suitable form or comprise any suitable material, such as a ferrite magnetic material or can be a functional heterostructure, depending on the acoustic device of which it will form a part. For example, in some embodiments it can include only a functional substrate, while in other embodiments it can take the form of a substrate combined with metal electrode layers, alternating acoustic mirrors, recessed cavities, etc. as needed for the desired mode of operation Target substrate or heterostructure 105 can be optionally coated with an adhesion layer 106, e.g., a thin polymer layer, that promotes good adhesion of the transferred piezoelectric device (i.e., piezoelectric layer 103 with contacts 104) without significantly impeding or attenuating transport of acoustic waves/phonons from the piezoelectric transducer to the target substrate or target heterostructure, though in many cases, the piezoelectric device can be transferred directly onto the target substrate without the need for any extra adhesion layer. This transfer printing process allows for the deterministic placement and alignment of individual devices on to the target substrate or target heterostructure as appropriate for the final purpose of the device.

Thus, in accordance with the present invention, a III-Nitride or PO acoustic transducer layer can be transferred to a desired functional target substrate or heterostructure that may not be compatible with the high quality growth process needed to form the transducer layer. The resulting heterostructure comprising the transferred acoustic device combines the useful properties and characteristics of the target substrate and heterostructure with the high quality acoustic transduction of the piezoelectric device.

In operation, the high-quality piezoelectric transducer 103 can now be used to excite acoustic waves/phonons and inject them into the target substrate or target heterostructure 105, with any interactions between these acoustic waves and physical characteristics (e.g., acoustic velocity, impedance, propagation loss, etc.) or phenomena (e.g., interactions between the acoustic waves/phonons and other wave/particles such as spin waves/magnons or electrons) of the target substrate or target heterostructure being available for use in the eventual application.

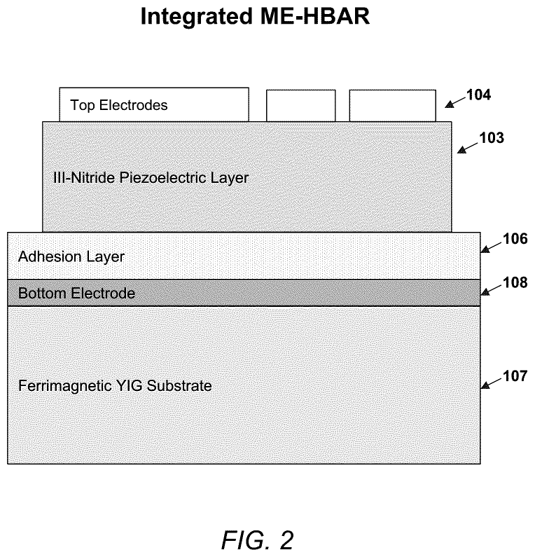

The block schematic in FIG. 2 illustrates an exemplary integrated magnetoelastic HBAR (ME-HBAR) produced via the transfer printing process in accordance with the present invention. In the exemplary device illustrated in FIG. 2, GaN-based epitaxial high overtone bulk acoustic resonators (epi-HBARs) were grown on a 6H—SiC substrate and the individual piezoelectric transducers were subsequently transferred to a ferrimagnetic yttrium iron garnet (Y₃Fe₅O₁₂ or YIG) substrate to form a magnetoelastic HBARs (ME-HBAR) comprising a III-Nitride (in this case a GaN-based) piezoelectric layer 103 on a YIG substrate 107, with the piezoelectric layer secured to the substrate by adhesion layer 106. Top and bottom electrodes 104 and 108 contact the piezoelectric layer 103 to provide electrical contact to the device.

In accordance with the present invention, the transfer of the epitaxial piezoelectric layer from its native substrate to the target YIG substrate is mediated by an epitaxially grown niobium nitride (NbN) TMN sacrificial layer and a commercially available transfer printing tool and process that can be scaled to industrial manufacturing. The transfer printing process decouples the highly optimized Group III-Nitride epitaxy process from the functional YIG target substrate. To the best of the inventors' knowledge, this is the first demonstration of integration of individual MEMS acoustic transducers using transfer printing.

The resulting YIG ME-HBARs can support low-loss propagation and confinement of both acoustic and spin waves simultaneously. Such hybrid phonon-magnon coupled devices can be used as sensors, magnetically tunable oscillators, filters, or parametric amplifiers, with applications for both classical and quantum signal processing systems. See J. Xu, et al., “Coherent Pulse Echo in Hybrid Magnonics with Multimode Phonons,” Physical Review Applied, vol. 16, p. 024009, 2021; N. I. Polzikova, et al., “Acoustic excitation and electrical detection of spin waves and spin currents in hypersonic bulk waves resonator with YIG/Pt system,” Journal of Magnetism and Magnetic Materials, vol. 479, pp. 38-42, 2019; I. Lisenkov, et al., “Magnetoelastic parametric instabilities of localized spin waves induced by traveling elastic waves,” Physical Review B, vol. 99, p. 184433, 2019; P. Chowdhury, et al, “Nondegenerate Parametric Pumping of Spin Waves by Acoustic Waves,” IEEE Magnetics Letters, vol. 8, pp. 1-4, 2017; and P. Chowdhury, et al., “Parametric Amplification of Spin Waves Using Acoustic Waves,” IEEE Transactions on Magnetics, vol. 51, pp. 1-4, 2015.

While ME-HBARs have been fabricated by evaporating/sputtering metals and piezoelectric layers on to YIG and other ferroic substrates, the fabrication and performance of such devices is constrained by nucleation dynamics, sputtered grain size/quality, crystallographic axis optimization, crystallographic defects, and thermal budgets of the deposition process, all of which restrict the type and quality of potential material combinations. See J. D. Adam, et al, “Magnetically Tunable High Overtone Microwave Resonators,” in 40th Annual Symposium on Frequency Control, 1986, pp. 392-393; and H. L. Salvo, et al., “Properties of Tunable Yig Hbars,” in IEEE 1987 Ultrasonics Symposium, 1987, pp. 337-340. In contrast, the method of the present invention full decouples the transducer synthesis and fabrication from the functional substrate or heterostructure providing for substrate agnostic design of acoustic and hybrid acoustic microsystems. This allows for maximized device performance via utilization of high quality epitaxial piezoelectric transducer layers combined with an optimal application-specific substrate or heterostructure without conventional limitations such as chemical/thermal budget, material incompatibility, or size.

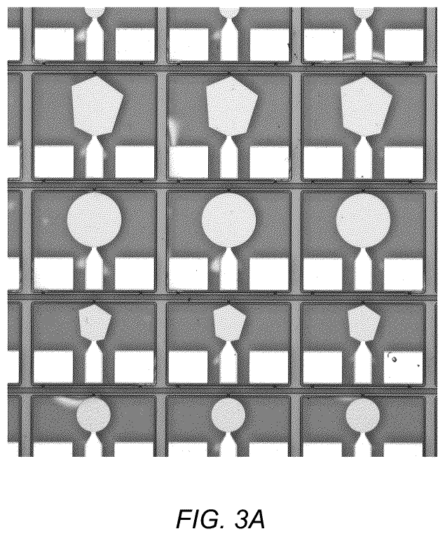

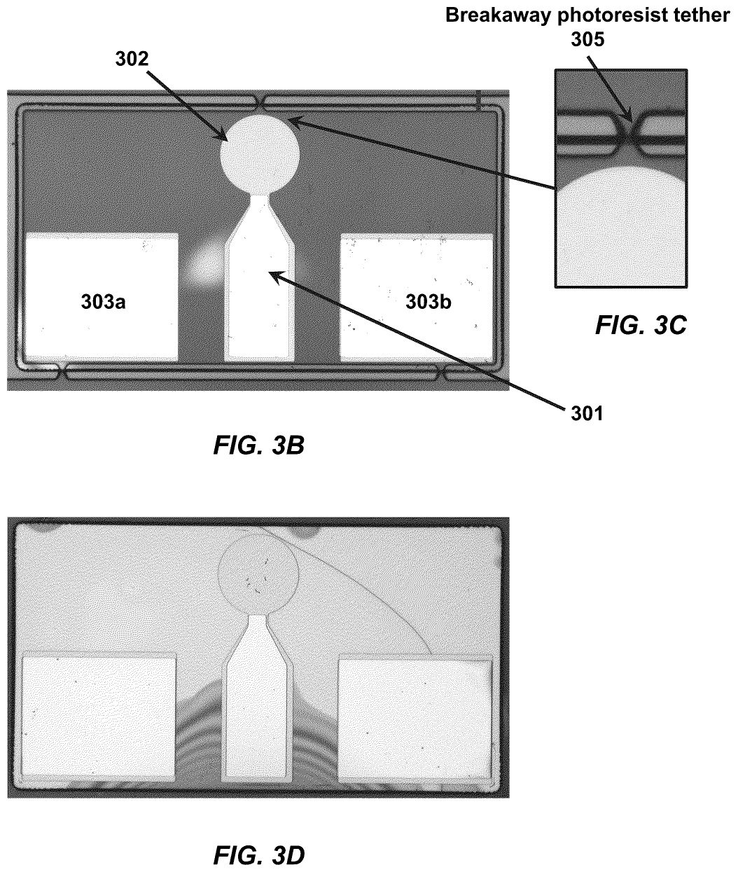

FIGS. 3A-3D illustrate aspects of fabrication of an exemplary ME-HBAR on a YIG substrate in accordance with the present invention.

The transfer printing process flow for the ME-HBAR follows the process described below. An array of AlGaN/GaN/AlN/NbN heterostructures are grown on a 6H—SiC host substrate by molecular beam epitaxy. The c-axis oriented AlGaN/GaN/AlN piezoelectric layers are grown at temperatures up to 725° C. The combination of the heterostructure and the epitaxial source substrate is carefully chosen to provide both the close lattice matching required for electronic-grade AlGaN/GaN and the acoustic impedance matching required for efficient acoustic power transfer. V. J. Gokhale, et al., “Engineering Efficient Acoustic Power Transfer in HBARs and Other Composite Resonators,” Journal of Microelectromechanical Systems, vol. 29, pp. 1014-1019, 2020.

For the purposes of creating just an acoustic epi-HBAR without GaN-based electronics, the AlGaN barrier is etched using a Cl₂/BCl₃ plasma to remove the 2D electron gas at the AlGaN/GaN interface. A Cr/Al top electrode is fabricated by electron beam evaporation and liftoff, and thick Au contact pads are deposited and patterned next to the transducer to provide a coplanar waveguide (CPW) for RF input signals.

Next, using a (Cl₂/BCl₃ plasma), trenches are etched around the individual devices shown in FIG. 3A to isolate the individual device and provide access to the underlying NbN sacrificial release layer

Such an isolated individual device is illustrated by the optical microscope image in FIG. 3B, and includes a AlGaN/GaN/AlN/NbN epitaxial heterostructure 301 with Cr/Al top electrode 302 and Au contact pads 303a/303b.

A photoresist (PR) layer is subsequently patterned to provide mechanical anchors on the SiC substrate and “breakaway” tethers 304 such as those illustrated in the inset image in FIG. 3C, which hold the HBAR in place during the release etch, with the PR layer further providing a protective layer on top of the HBAR during transfer.

The NbN layer is then etched using XeF₂ vapor phase etching, releasing the GaN acoustic transducer in a manner described in B. P. Downey, et al., “XeF₂ etching of epitaxial Nb2N for liftoff or micromachining of III-N materials and devices,” Journal of Vacuum Science & Technology A: Vacuum, Surfaces, and Films, vol. 35, p. 05C312, 2017, while leaving it suspended in place on the substrate by the PR breakaway tether.

In parallel to the processing of the transducers on the 6H—SiC host substrate, a Cu thin film electrode is evaporated on to a <111> YIG target substrate. YIG is a magnetostrictive and ferrimagnetic material well known for its low acoustic and spin wave damping. The Cu film has low acoustic mismatch with YIG, and replaces NbN as the bottom electrode in the transducer. A diluted Intervia 8023-10 interlayer dielectric (ILD) is spun onto the Cu/YIG target substrate forming an adhesion layer having a thickness of about 10 nm. A commercially available transfer printing tool (e.g., the X-CELEPRINT tool currently known in the art or other suitable transfer printing tool) is then used to transfer the individual GaN acoustic transducer from the 6H—SiC host substrate to specific locations on the Cu/YIG target substrate, forming an Al/GaN/AlN/Cu/YIG ME-HBAR as shown in FIG. 3D. A UV flood exposure and bake cures the ILD, and O₂ plasma removes ILD from the open areas of the target substrate. Critically, unlike the 725° C. MBE step used to grow the heterostructure, a post-transfer hotplate bake at 185° C. is the highest process temperature step for the YIG target substrate.

To verify the basic operation of the ME-HBAR created using the transfer printing process, the RF performance of both the epi-HBAR (before transfer printing) and the ME-HBAR (after transfer printing) was measured to evaluate and verify relevant acoustic parameters of the devices.

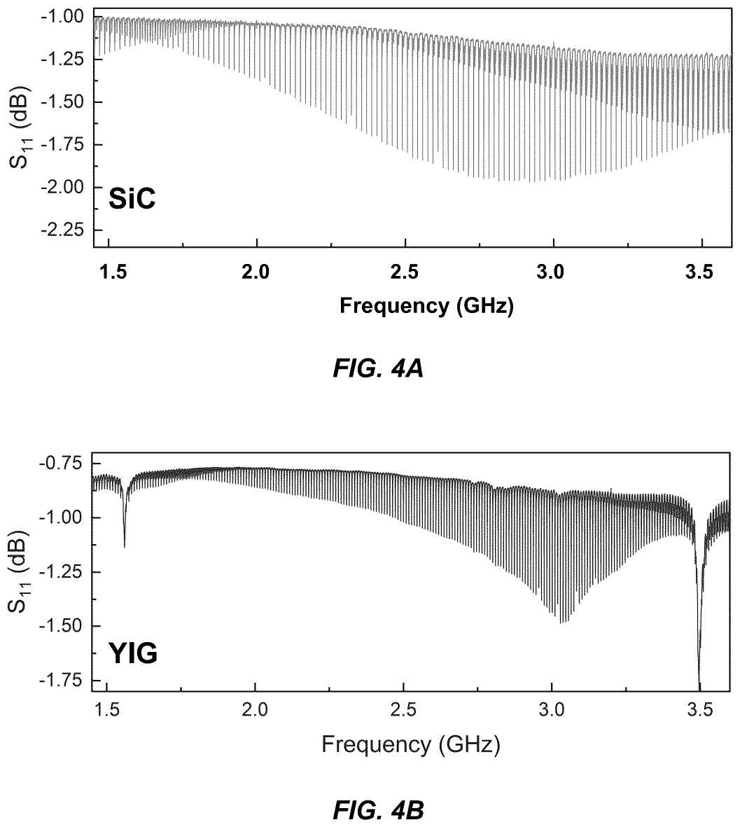

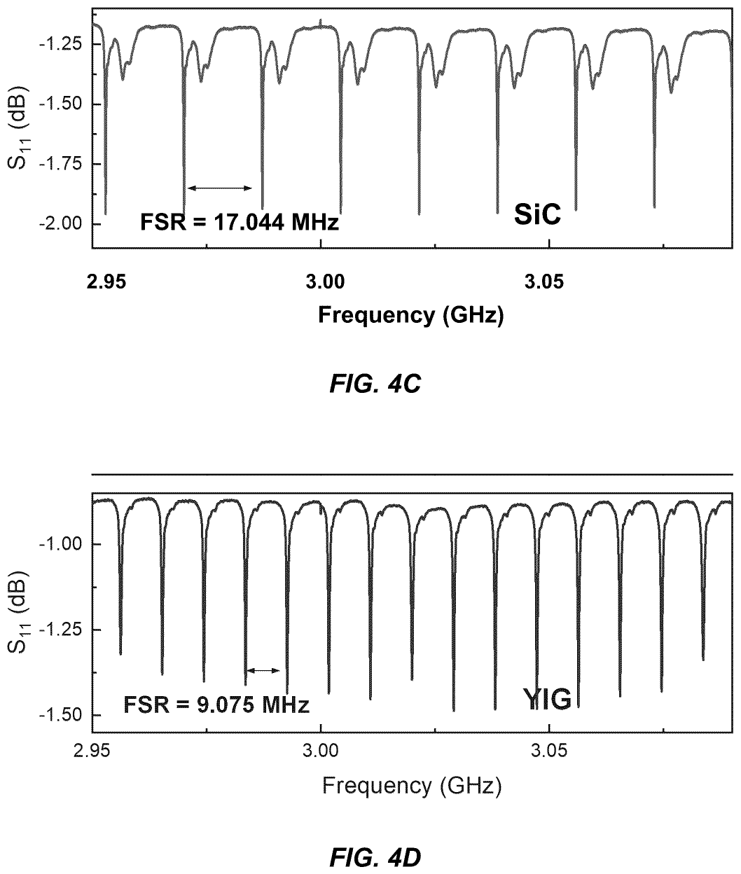

The RF reflection spectra for both configurations is shown by the plots in FIGS. 4A-4D, and shows both expected changes in the spectral envelope (FIGS. 4A and 4B) and in the free spectral range (FSR) of the HBAR response due to the difference in acoustic velocities of the SiC (FIG. 4C) and the YIG substrates (FIG. 4D). To a first order, the FSR for any HBAR can be approximated as FSR=v/2t, where v is the substrate acoustic velocity and t is the substrate thickness. A detailed study of the FSR, its dependence on the heterostructure, and its use as a diagnostic for impedance matching can be found in prior work. See V. J. Gokhale, et al., Journal of Microelectromechanical Systems, supra.

Here, FSR values of 17.14 MHz and 9.10 MHz are experimentally observed for the epi-HBAR (FIG. 4C) and ME-HBAR (FIG. 4D). respectively. Based on the substrate thicknesses, we can extract acoustic velocities of 12,684 m/s for the epi-HBAR and 6370 for the ME-HBAR. Extracted values are close to values from the literature: 13,300 m/s for SiC and 6220 m/s for <111> YIG. See J. Xu et al., supra; see also H. M. Chou, et al., “Characterization of some mechanical properties of polycrystalline yttrium iron garnet (YIG) by non-destructive methods,” Journal of Materials Science Letters, vol. 7, pp. 1217-1220, 1988. As shown by the plot in FIG. 4C, measured (f×Q) products for both the epi-HBAR and the ME-HBAR show that there is no significant degradation in performance due to the transfer printing process.

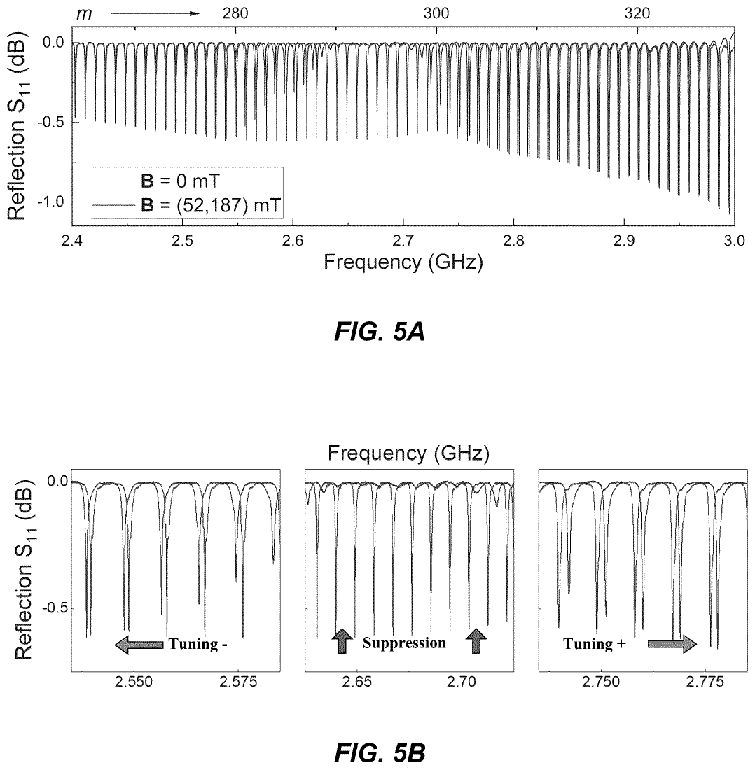

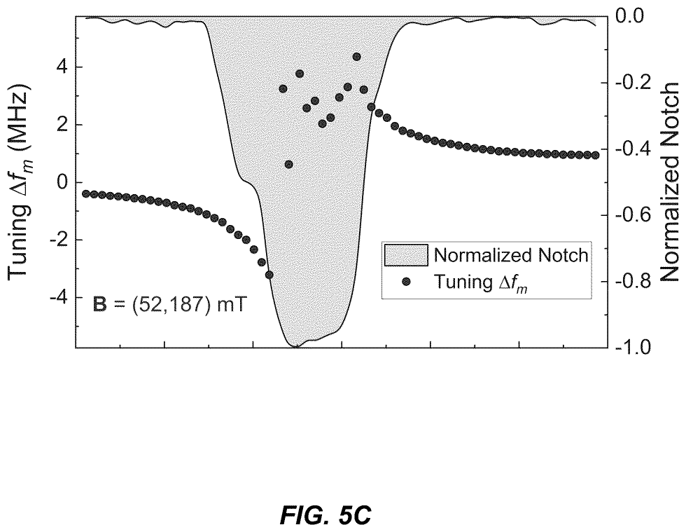

In order to further characterize their magnetoelastic performance, the transfer printed ME-HBARs are mounted on a rotating stage within the gap of a laboratory electromagnet, and measured using RF probes. The frequency response of the ME-HBARs is measured as a function of magnetic field, B. Two representative measured responses are shown by the plots in FIGS. 5A-5B, for a zero applied magnetic field, and for an applied magnetic field of Bₓ=52 mT (in-plane component), and B_{z}=187 mT (normal component). In a spectral region near 2.7 GHz, coupling and hybridizing of the acoustic waves with corresponding spin wave modes at this magnetic bias is observed, see C. Kittel, “Interaction of Spin Waves and Ultrasonic Waves in Ferromagnetic Crystals,” Physical Review, vol. 110, pp. 836-841, 1958. The hybridization of acoustic and spin waves leads to a both a suppression of the acoustic modes (near the hybridization frequency), and a shift in the resonant frequency of the acoustic modes in a region around the hybridization frequency. In a part of this region near the hybridization frequency, the phonon-magnon coupling near completely attenuates the mechanical mode, effectively switching it off, as shown by the magnified part of the spectrum shown in in FIG. 5B. The acoustic modes below and above the hybridization frequency undergo negative and positive tuning respectively, as shown in FIG. 5B.

The normalized acoustic mode suppression and the acoustic mode tuning are both shown clearly in FIG. 5C for the given magnetic bias (Bₓ=52 mT and B_{z}=187 mT). Near complete mode suppression or ‘notching’ is seen near 2.65 GHz while negative and positive tuning is clearly seen on either side of the notch.

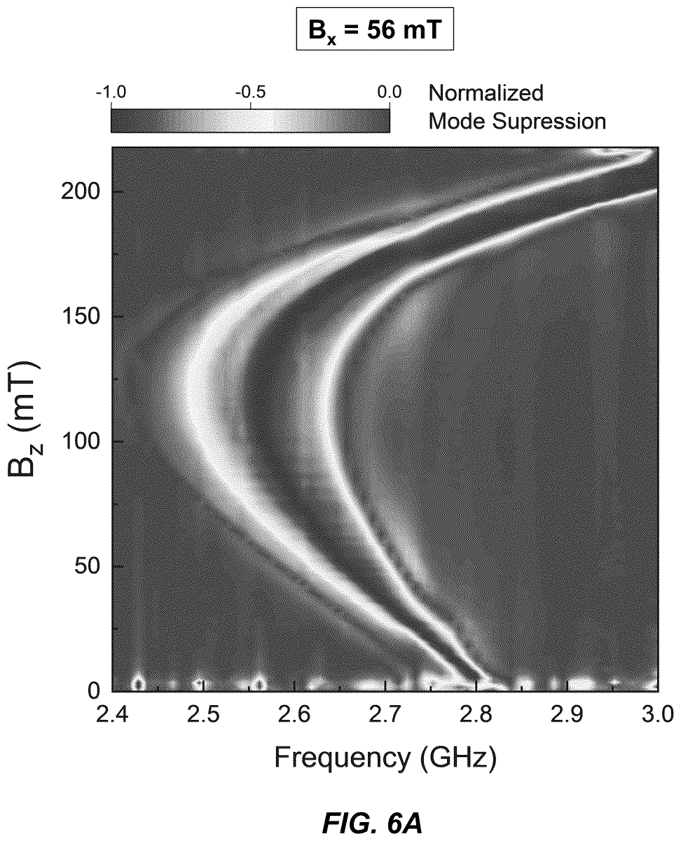

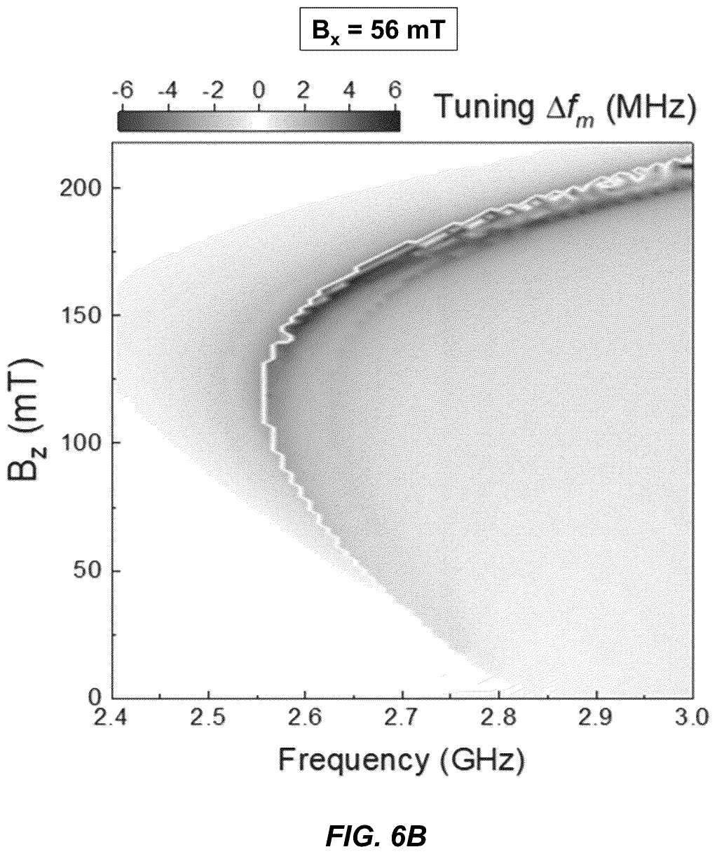

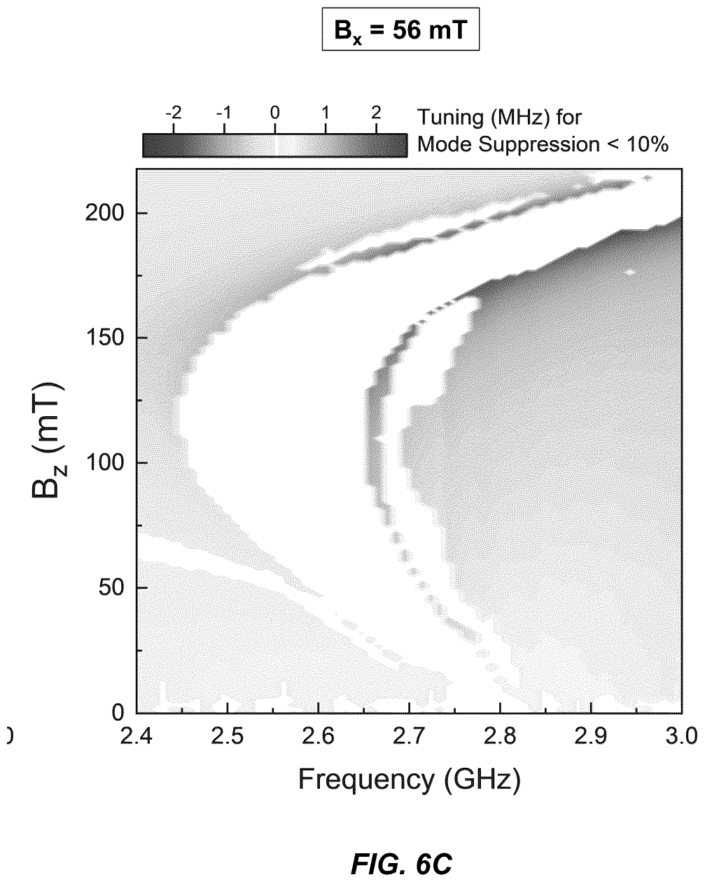

The mode suppression and the frequency tuning due to acoustic-spin wave hybridization is further demonstrated by the plots in FIGS. 6A-6C. In each of these plots, Bₓ=56 mT (in-plane component of magnetic bias field) is fixed while B_{z} (normal component of magnetic bias field) is varied. FIG. 6A shows a map of acoustic mode suppression for all acoustic modes between 2.4 GHz and 3 GHz. We observe a non-linear dependence of the hybridization frequency on the normal magnetic field. FIG. 6B shows the corresponding frequency tuning of the acoustic modes. For practical applications such as filtering and frequency synthesis, it is desirable to achieve lossless dynamic tuning. FIG. 6C provides a corresponding map of frequency tuning under the condition that the mode suppression is less than 10%. The 10% threshold is an arbitrary one, used here to demonstrate the concept. This near-lossless tuning is an indicator that it is possible to achieve meaningful tuning in some modes while maintaining an acceptable amount of signal suppression.

The dependence of the acoustic mode suppression and the acoustic mode tuning on the magnetic bias field components Bₓ and B_{z}, as described above, additionally implies that the frequency response of the ME-HBAR can be controlled solely by changing the angle of the applied magnetic bias field while maintaining a constant amplitude |B|. Experimental data on the ME-HBAR described above confirm that for a constant magnetic bias field amplitude, we can create an acoustic notch and tune its width up to 140 MHz.

### Advantages and New Features

The use of transfer printed acoustic devices on arbitrary substrates makes it practical to implement a broad combination of functionalities to be integrated with the best-in-class optimally grown single crystal piezoelectric transducers. High quality multi-domain coupled devices (phonon-photon, phonon-magnon, phonon-semiconductor, and phonon-superconductor) can be quickly implemented without needing to co-fabricate and optimize the piezoelectric film on a range of substrates, many of which are not suitable for epitaxy. The transfer printing process can also be used to integrate drive, control, and readout electronics on the same substrate, without needing to grow electronic grade semiconductors on the target substrate.

In addition, further processing can be performed on the transferred acoustic device once it is on the functional substrate, e.g. signal routing, electrodes, etc. For instance, one could just transfer the piezoelectric material by itself (no electrodes) then deposit electrodes post-transfer if that was advantageous.

### Alternatives

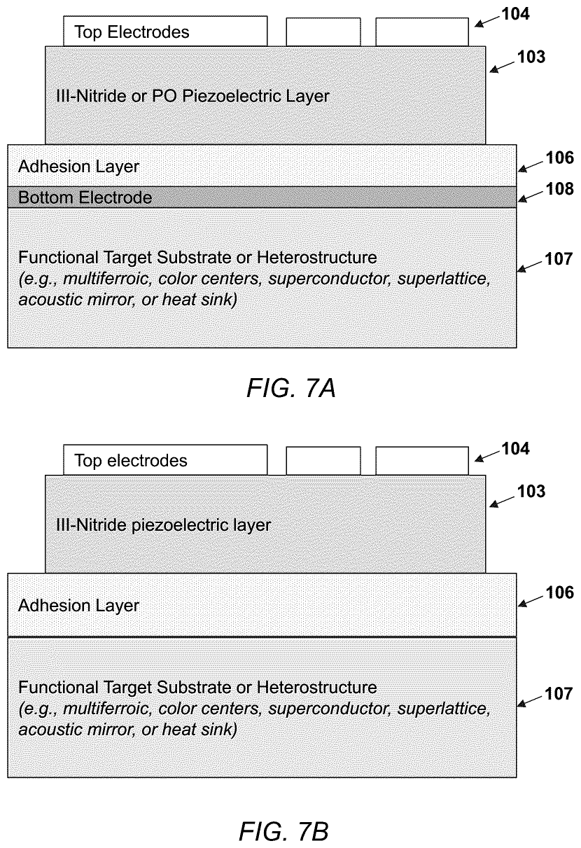

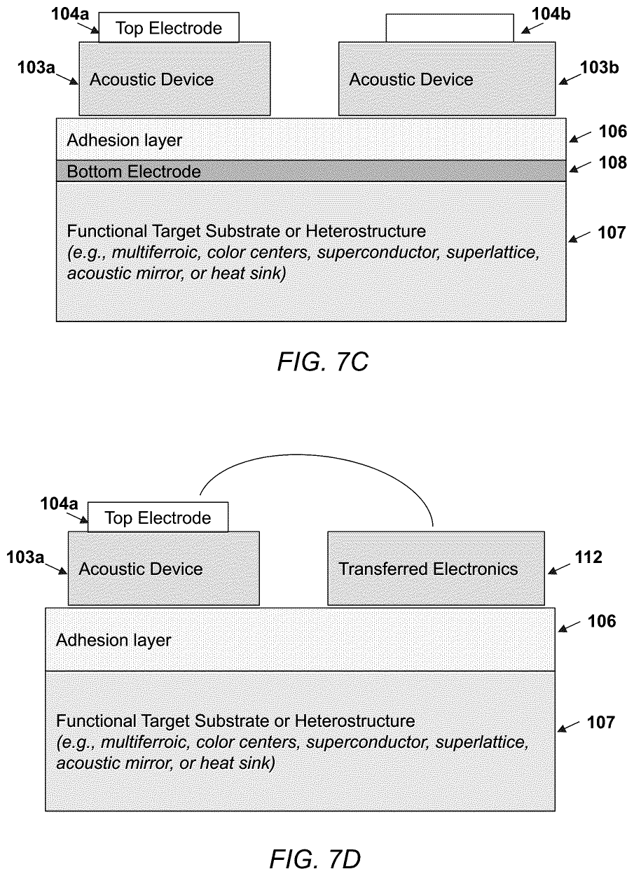

In addition to the transferred acoustic device detailed above, FIGS. 7A-7D illustrate some exemplary alternative configurations for integrated acoustic devices made by transferring optimally grown piezoelectric transducer to a functional target substrate or heterostructure.

For example, an acoustic device formed by the transfer printing process in accordance with the present invention can take the form of a bulk acoustic wave (BAW) device as shown in FIG. 7A, which includes a III-Nitride or perovskite oxide (PO) piezoelectric transducer layer 103 with top and bottom electrodes 104 and 108 secured to a target substrate or heterostructure 107 by means of an optional adhesion layer 106. Such a structure can exhibit one or more physical phenomena that could be coupled to the acoustic phonons, e.g., spin waves, electrons/holes, spin qubits, etc.

Similarly, as shown in FIG. 7B, a surface acoustic wave (SAW) or Lamb wave device comprising a piezoelectric transducer layer 103 having top electrodes 104 only secured to a target substrate 107 can be formed using the transfer printing process in accordance with the present invention.

In an alternative embodiment such as that illustrated in FIG. 7C, multiple acoustic devices comprising a piezoelectric transducer layer 103 and top contacts 104 can be transferred to a single target substrate 107, to enable a single structure to operate in different modes or different frequencies.

Finally, in an alternative embodiment such as that illustrated in FIG. 7D, a combination device comprising one or more acoustic devices transfer-printed to a target substrate in accordance with the present invention can be combined with other transferred electronic components, such as drive, control, and/or readout electronics, to provide an integrated acoustic device situated on a target substrate.

In summary, this invention enables the decoupling of the growth of thin film acoustic transducers from their eventual form and embodiment, and the creation of acoustic devices and systems capable of interacting with multiple physics domains. It shall enable custom solutions to problems that cannot easily be solved by a single self-compatible fabrication process by using the best combination of materials that would be otherwise incompatible.

Although particular embodiments, aspects, and features have been described and illustrated, one skilled in the art would readily appreciate that the invention described herein is not limited to only those embodiments, aspects, and features but also contemplates any and all modifications and alternative embodiments that are within the spirit and scope of the underlying invention described and claimed herein. The present application contemplates any and all modifications within the spirit and scope of the underlying invention described and claimed herein, and all such modifications and alternative embodiments are deemed to be within the scope and spirit of the present disclosure.

What is claimed is:

1. A method for fabricating an integrated acoustic device on an arbitrary functional substrate, comprising:
epitaxially growing a sacrificial layer on a host substrate;
epitaxially growing a piezoelectric transducer on the sacrificial layer;
forming at least one top metal electrode on a top surface of the piezoelectric transducer;
etching the sacrificial layer to release the piezoelectric transducer and removing the piezoelectric transducer from the host substrate while maintaining its epitaxial nature and materials properties; and
transferring the released piezoelectric transducer to the arbitrary functional substrate;
wherein the physical phenomena from the piezoelectric transducer and the arbitrary functional substrate interact to form a hybrid acoustic microsystem comprising the piezoelectric transducer and the arbitrary functional substrate;
wherein the arbitrary functional substrate provides critical functionality to the acoustic microsystem.

2. The method according to claim 1, wherein the piezoelectric transducer comprises a piezoelectric thin film.

3. The method according to claim 1, wherein the piezoelectric transducer comprises an epitaxial III-Nitride piezoelectric transducer.

4. The method according to claim 1, wherein the piezoelectric transducer comprises a piezoelectric heterostructure.

5. The method according to claim 1, wherein the piezoelectric transducer comprises a GaN, AlN, ScAlN, InAlN, InGaN, or AlGaN-based heterostructure.

6. The method according to claim 1, wherein the piezoelectric transducer comprises a perovskite oxide piezoelectric transducer.

7. The method according to claim 1, wherein the host substrate comprises 4H—SiC, 6H—SiC, or sapphire.

8. The method according to claim 1, wherein the functional substrate comprises a ferrite magnetic material.

9. The method according to claim 1, wherein the functional substrate comprises a ferrite yttrium-iron-garnet (YIG) substrate.

10. The method according to claim 1, further comprising depositing an adhesion layer on an upper surface of the arbitrary substrate and placing the released piezoelectric transducer onto the adhesion layer.

11. The method according to claim 1, wherein the integrated acoustic device comprises a magnetoelastic high-overtone bulk acoustic resonator (ME-HBAR).

12. The method according to claim 1, wherein the piezoelectric transducer comprises an AlGaN/GaN/AlN/NbN heterostructure grown on a 6H—SiC host substrate by molecular beam epitaxy.

13. The method according to claim 1, wherein the sacrificial layer is a transition metal nitride (TMN) layer.

14. The method according to claim 1, wherein the sacrificial layer is niobium nitride (NbN).
